(19) United States
(12) Patent Application Publication
(10) Pub. No.: US 2025/0311132 A1
(43) Pub. Date: Oct. 2, 2025

(54) HOUSING FOR AN ELECTRICAL OR ELECTRONIC DEVICE

(71) Applicant: BorgWarner Inc., Auburn Hills, MI (US)

(72) Inventors: Thomas Glass, Rockenhausen (DE); Kai Homann, Kelkheim (DE); Andreas Köpper, Bürstadt (DE)

(21) Appl. No.: 19/086,716

(22) Filed: Mar. 21, 2025

(30) Foreign Application Priority Data
Mar. 28, 2024 (DE) 10 2024 108 940.7

(51) Int. Cl. H05K 5/06; H05K 5/04; H05K 5/13

(52) U.S. Cl. CPC H05K 5/069; H05K 5/04; H05K 5/13

(57) ABSTRACT

A housing for an electrical or electronic device is described, with a first housing part made of metal and a second housing part made of metal. The first housing part has a groove that contains a sealant, and in which one or a plurality of ribs of the second housing part engage. In accordance with this disclosure, provision is made for the rib or ribs to be designed as crimping ribs.

### RELATED APPLICATIONS

This application claims priority to DE 10 2024 108 940.7, filed Mar. 28, 2024, the entire disclosure of which is hereby incorporated herein by reference.

### BACKGROUND

This disclosure relates to a housing for an electrical or electronic device. Housings for electrical or electronic devices are disclosed generally in DE 195 28 313 A1 and DE 20 2016 106 815 A1.

EMC shielding and sealing against moisture are constant requirements for such housings. For reliable EMC shielding, electrically conductively connected metal housing parts are required. In conventional housings, this contact is ensured by electrically conductive adhesive, which connects two metal housing halves, and at the same time provides a seal against moisture.

Electrically conductive adhesive contains metal particles or other electrically conductive particles, and is therefore considerably more expensive than conventional adhesive, which is non-conductive. In addition, the electromagnetic attenuation thereby achieved is less effective than with a metallic connection.

### SUMMARY

This disclosure teaches a way of producing housings for electrical or electronic devices that ensures both reliable EMC shielding over the service life of the electrical or electronic device, and also sealing against moisture.

A housing in accordance with this disclosure is formed from a first metallic housing part, which has a groove, and a second metallic housing part, which has crimping ribs that engage in the groove. A reliable electrical contact, and thus improved EMC shielding between the two housing parts, is achieved by way of the engagement of crimping ribs in the groove.

Crimping ribs are dimensioned such that plastic deformation of the rib and/or the groove occurs when they are pressed into the groove. Crimping ribs thus reliably ensure a good electrical contact between the two housing parts; in particular, the plastic deformation of the crimping rib and groove can result in an advantageous cold welding of the two housing parts. A circumferential crimping rib can engage in a circumferential groove. However, it is also possible to use a plurality of ribs, arranged at a distance apart from each other, which engage in a groove, preferably a circumferential groove.

Crimping ribs are deformed in the course of insertion into the groove, particularly in the direction transverse to the direction of insertion. The groove can, for example, have a side wall that has an inclined wall section, which the crimping rib encounters as it is inserted into the groove. When the crimping rib is pressed into the groove, the crimping rib then slides along the inclined wall section, and is deformed in the process. This generates a force that presses the rib against the side wall, deforms the rib, and can then lead to a cold welding process.

The inclined wall section may be a curved surface or a flat surface that runs at an angle to the direction of insertion. The inclined surface may be adjoined by a flat wall section that runs in the direction of insertion of the crimping rib, and against which the crimping rib lies flat in the assembled state. The inclined wall section may be located between two flat wall sections that run parallel to the direction of insertion. Alternatively, the crimping rib can also have a side surface with an inclined section which, when pressed into the groove, slides along the edge of the groove such that the crimping rib is deformed, and a clamping force is generated, which presses the crimping rib against the side wall of the groove.

The groove contains a sealant, for example, a rubber seal, an O-ring section, or an adhesive, in particular an electrically insulating adhesive, for example, a silicone adhesive.

An advantageous refinement of this disclosure provides for the first housing part and the second housing part to be connected by means of screws. In this manner, a mechanically resilient connection of the two housing parts can be achieved even before the adhesive hardens. The screws are preferably self-tapping or self-cutting screws, as these are particularly easy to apply.

### BRIEF DESCRIPTION OF THE DRAWINGS

The above-mentioned aspects of exemplary embodiments will become more apparent and will be better understood by reference to the following description of the embodiments taken in conjunction with the accompanying drawings, wherein:

FIG. 1 shows an example of a housing; and

FIG. 2 shows a cross-sectional detail of the housing.

### DESCRIPTION

The embodiments described below are not intended to be exhaustive or to limit the invention to the precise forms disclosed in the following description. Rather, the embodiments are chosen and described so that others skilled in the art may appreciate and understand the principles and practices of this disclosure.

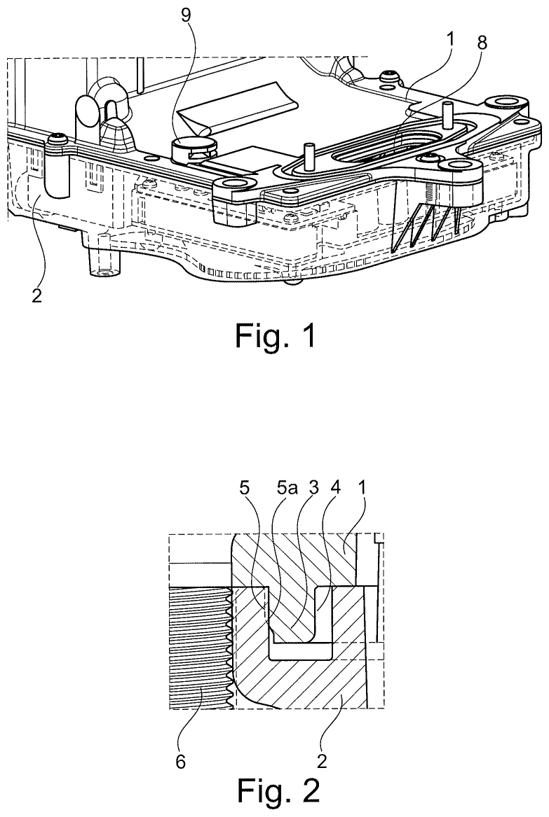

FIG. 1 shows a housing for an electrical or electronic device, for example, an electronic control unit for an electric turbocharger, a fluid or air heater, an inverter, an electric motor, or a fan. The housing has a first housing part 1 and a second housing part 2, each of which is made of metal, for example, an aluminium-based alloy. The housing shown thus has two metal housing halves.

One of the two housing parts, for example, housing part 1, has crimping ribs 3 that engage in a groove 4 in the other housing part, housing part 2, in the example of embodiment shown.

An example of the design of a crimping rib is shown in particular in FIG. 2, which shows a cross-sectional detail of the housing. The crimping rib 3 shown can be designed as a circumferential crimping rib or as one of a plurality of crimping ribs arranged at a distance apart from each other.

When the crimping rib 3 is pressed in, plastic deformation of the crimping rib 3 and a side wall 5 of the groove 4 occurs. This plastic deformation leads to cold welding of the two housing parts 1, 2, namely, of the crimping rib 3 with a side wall 5 of the groove 4. The two housing parts 1, 2 are thus materially bonded to each other in the region of the crimping rib 3. Advantageously, this provides a good electrical contact between the two housing parts 1, 2.

In the embodiment shown, the side wall 5 of the groove 4 has an inclined section 5a, for example, an inclined surface. When the crimping rib 3 is pressed into the groove 4, the crimping rib 3 slides along this section and is deformed, for example, by 0.1 mm to 0.3 mm, in the direction transverse to the direction of insertion. The inclined wall section can run between two wall sections extending linearly in the direction of insertion.

The groove 4 contains a non-conductive adhesive, for example, a silicone adhesive. Non-conductive adhesives are sometimes referred to as insulating adhesives, and usually have a resistivity of 10⁸ Ω·cm, or more. Such adhesives are available at a lower cost than electrically conductive adhesives that have been made conductive by the addition of metal or graphite particles. The adhesive in the groove 4 effects a reliable seal of the connection between the two housing parts 1, 2, in particular against the ingress of moisture.

In addition, the two housing parts 1, 2 are connected by screws 6. These screws 6 secure the connection between the two housing parts 1, 2, in particular until the adhesive has hardened or dried. The screws 6 can be designed as self-tapping or self-cutting screws to simplify the assembly.

One of the two housing parts 1, 2, in the example of embodiment shown housing part 1, has an opening 8, into which a housing of an electrical connector is inserted.

While exemplary embodiments have been disclosed hereinabove, the present invention is not limited to the disclosed embodiments. Instead, this application is intended to cover any variations, uses, or adaptations of this disclosure using its general principles. Further, this application is intended to cover such departures from the present disclosure as come within known or customary practice in the art to which this invention pertains and which fall within the limits of the appended claims.

### LIST OF REFERENCE SYMBOLS

1 Housing part
2 Housing part
3 Crimping rib
4 Groove
5 Side wall of the groove
5a Inclined section of the side wall
6 Screw
8 Opening
9 Plastic housing

What is claimed is:

1. A housing for an electrical or electronic device, the housing comprising:
a first housing part made of metal and having a groove containing a sealant; and
a second housing part made of metal and having one or more crimping ribs that engage in the groove.

2. The housing according to claim 1, wherein the two housing parts are additionally connected by screws.

3. The housing according to claim 2, wherein the screws are self-tapping screws or self-cutting screws.

4. The housing according to claim 1, wherein the crimping rib or crimping ribs are cold welded to a side wall of the groove.

5. The housing according to claim 1, wherein the sealant is an adhesive.

6. The housing according to claim 1, wherein the sealant is an electrically isolating adhesive.

7. The housing according to claim 1, wherein the first housing part and the second housing part are made of an aluminium-based alloy.

8. The housing according to claim 1, wherein the groove has a side wall, which has an inclined wall section, which the crimping rib encounters as it is inserted into the groove, then slides against it and is deformed in the process, wherein a clamping force is generated, which presses the crimping rib against the side wall.

9. The housing according to claim 8, wherein the inclined wall section is adjoined by a wall section that extends linearly in the direction of insertion.

10. The housing according to claim 8, wherein the inclined wall section lies between two wall sections that extend linearly in the direction of insertion.

11. The housing according to 8, wherein the inclined wall section forms an inclined surface that the crimping rib encounters as it is inserted into the groove.

12. The housing according to claim 1, wherein the groove is a circumferential groove.

13. The housing according to claim 1, wherein the first housing part or the second housing part has an opening, into which a housing of an electrical connector is inserted.
